(19) United States
(12) Patent Application Publication
(10) Pub. No.: US 2023/0232579 A1
(43) Pub. Date: Jul. 20, 2023

(54) INTEGRATED LIQUID-COOLED HEAT DISSIPATION DEVICE

(71) Applicant: Dongguan city think-cool thermal dissipation technologies Co., Ltd., Dongguan City (CN)

(72) Inventors: Xiao FAN, Dongguan City (CN); Haohui TANG, Dongguan City (CN); Haoqiang DENG, Dongguan City (CN)

(21) Appl. No.: 17/651,893

(22) Filed: Feb. 21, 2022

(30) Foreign Application Priority Data
Jan. 20, 2022 (CN) 202220155217.X

(51) Int. Cl. H05K 7/20

(52) U.S. Cl. CPC H05K 7/20272; H05K 7/20263

(57) ABSTRACT

The present invention relates to the technical field of liquid-cooled heat dissipation, and in particular to an integrated liquid-cooled heat dissipation device. The heat dissipation device includes a first water chamber, a pumping device and a first interface. The first interface is mounted on one side of the first water chamber. The pumping device is provided in an embedded manner in the first water chamber, and the pumping device includes a water pump water chamber which is in communication with the first interface and an interior of the first water chamber. An objective of the present invention is to provide an integrated liquid-cooled heat dissipation device, which, through the rational design of a pumping device and a heat dissipation device, solves the problem that the integrated pumping and dissipation structure cannot meet the general space requirements.

### TECHNICAL FIELD

The present invention relates to the technical field of liquid-cooled heat dissipation, and in particular to an integrated liquid-cooled heat dissipation device.

### BACKGROUND

At present, heat dissipation apparatuses for cooling down computer CPUs, video cards, electronic instrument chips and other apparatuses usually take the form of a water-cooled heat sink, which basically consists of three parts, namely, a heat absorption device, a pumping device and a heat dissipation device, which are connected to form a closed liquid circulation loop. The heat absorption device is connected to a heat generating element, and the pumping device is used to provide power for liquid to circulate in the loop. The three parts are assembled and fixed by means of external connection pipes, therefore, this design has the disadvantages of occupying a relatively large space, being inconvenient for installation and operation, having high requirements for installation space, and having poor installation flexibility, so its application is greatly limited.

Although integrated pumping and dissipation (that is, pumping device and heat dissipation device) design schemes are currently available in the market, due to the defect in the positional design of the pumping device, the size of the heat dissipation device is too large. As a result, this kind of water-cooled heat sink is only suitable for customized environments and cannot meet the space requirements in conventional environments.

### SUMMARY

In order to overcome the shortcomings and deficiencies in the related art, the present invention aims to provide an integrated liquid-cooled heat dissipation device, which, through the rational design of a pumping device and a heat dissipation device, solves the problem that the integrated pumping and dissipation structure cannot meet the general space requirements.

The present invention is achieved by the following technical scheme:

an integrated liquid-cooled heat dissipation device, including a first water chamber, a pumping device and a first interface, where the first interface is mounted on one side of the first water chamber, the pumping device is provided in an embedded manner in the first water chamber, and the pumping device includes a water pump water chamber which is in communication with the first interface and an interior of the first water chamber.

In the integrated liquid-cooled heat dissipation device, the pumping device further includes a water pump base, a water pump shell and an impeller, the first water chamber is provided with a first opening, and the water pump base is provided in an embedded manner in the first opening; and the water pump base is provided with a receiving cavity with an opening end, the water pump shell is provided in an embedded manner in the receiving cavity, the water pump water chamber is formed between the water pump shell and the water pump base, and the impeller is received in the water pump water chamber.

In the integrated liquid-cooled heat dissipation device, the water pump base is provided with a first water port located below a rotating shaft of the impeller; and a second water port, which is in communication with the water pump water chamber, is further provided on one side of the water pump base, and the second water port is in communication with the first interface.

In the integrated liquid-cooled heat dissipation device, the first water chamber is internally provided with a partition plate for partitioning the first water chamber, the first water chamber is partitioned by the partition plate to form a second water chamber and a third water chamber, and the pumping device is provided in an embedded manner in the second water chamber.

In the integrated liquid-cooled heat dissipation device, the heat dissipation device further includes a fourth water chamber, a plurality of cooling tubes and a plurality of heat dissipation structure devices, where the plurality of heat dissipation structure devices are arranged at intervals, and each cooling tube is arranged between adjacent heat dissipation structure devices; and each of the plurality of cooling tubes has one end in communication with a fourth water chamber, some of the cooling tubes have the other end in communication with the first water chamber, and the remaining cooling tubes have the other end in communication with the second water chamber.

In the integrated liquid-cooled heat dissipation device, the heat dissipation structure devices are heat dissipation fins or heat dissipation wavy plates.

The present invention has the following beneficial effects: an integrated liquid-cooled heat dissipation device of the present invention adopts the scheme that the pumping device and the first water chamber are integrally arranged, and the pumping device is embedded in the first water chamber, so that compared with the conventional heat dissipation device, the thickness of the heat dissipation device of the present invention is unchanged, thereby greatly reducing the occupied space and increasing the applicability of the present invention in the conventional environments; and due to the integrated design of the pumping device and the heat dissipation device, the circulation distance of the liquid in the heat dissipation device is reduced, the power attenuation of the pumping device is less, and the heat exchange effect of the present invention is also improved.

### BRIEF DESCRIPTION OF DRAWINGS

The present invention will be further illustrated with reference to the accompanying drawings, but the embodiments in the accompanying drawings do not constitute any limitation to the present invention. For those of ordinary skill in the art, other drawings can be obtained according to the following drawings without involving any creative efforts.

FIG. 1 is a schematic perspective structural view of the present invention.

FIG. 2 is a schematic exploded structural view of the present invention.

FIG. 3 is a sectional view of the present invention.

FIG. 4 is a schematic exploded structural view of a pumping device.

FIG. 5 is a schematic structural view of a water pump base.

### LIST OF REFERENCE NUMERALS

First water chamber 100; Second water chamber 101; Third water chamber 102; First interface 103; Partition plate 104; Second interface 105; First opening 106;

Pumping device 200; Water pump water chamber 201; Water pump base 202; Water pump shell 203; Impeller 204; Receiving cavity 205; First water port 206; Second water port 207; Stator 208; Rotor 209; Water pump cover 210; Main board 211; Screw 212;

Fourth water chamber 301; Cooling tube 302; Heat dissipation structure device 303.

### DETAILED DESCRIPTION

In order to make the above-mentioned objective, features and advantages of the present invention more obvious and easier to understand, the specific embodiments of the present invention will be described in detail below with reference to the accompanying drawings. In the following description, numerous specific details are set forth to facilitate full understanding of the present invention. However, the present invention can be implemented in many other ways different from those described herein, and those skilled in the art can make similar improvements without violating the connotation of the present invention, so the present invention is not limited by the specific embodiments disclosed below.

In the description of the present invention, it should be understood that, descriptions relating to orientation, for example, orientation or positional relationships indicated by “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, etc. are based on the orientation or positional relationships shown in the accompanying drawings, and are to facilitate the description of the present invention and simplify the description only, rather than indicate or imply that the device or element mentioned must have a specific orientation or be constructed and operated in a specific orientation, and therefore cannot be construed as limiting the present invention.

In addition, the terms “first” and “second” are for the purpose of description only and should not be construed as indicating or implying relative importance or implicitly indicating the number of technical features indicated. Therefore, the features defined with “first” and “second” may explicitly or implicitly include at least one of the features. In the description of the present invention, the term “a plurality of” means at least two, for example, two or three or more, unless otherwise explicitly and specifically defined.

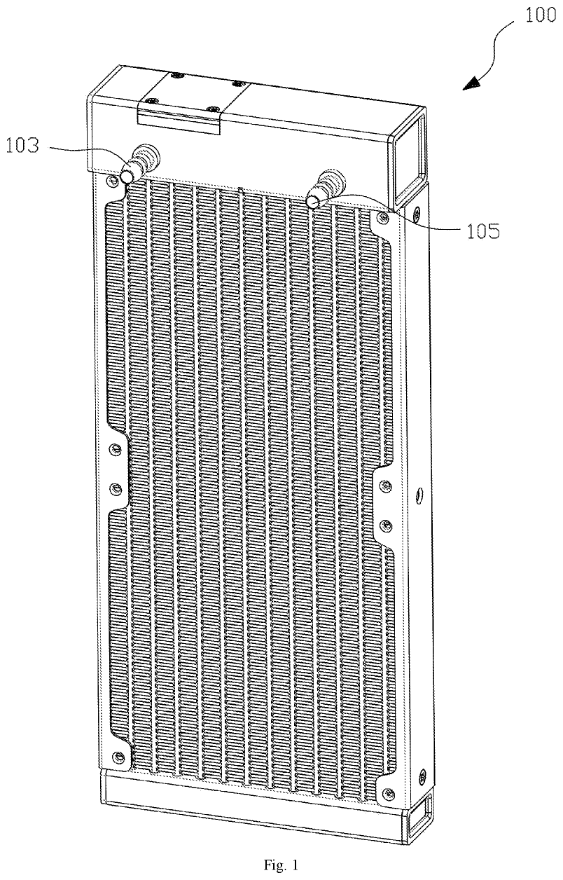

As shown in FIGS. 1-5, an embodiment of the present invention discloses an integrated liquid-cooled heat dissipation device, including a first water chamber 100, a pumping device 200 and a first interface 103. The first interface 103 is mounted on one side of the first water chamber 100, the pumping device 200 is provided in an embedded manner in the first water chamber 100, and the pumping device 200 includes a water pump water chamber 201. The water pump water chamber 201 is in communication with the first interface 103 and an interior of the first water chamber 100.

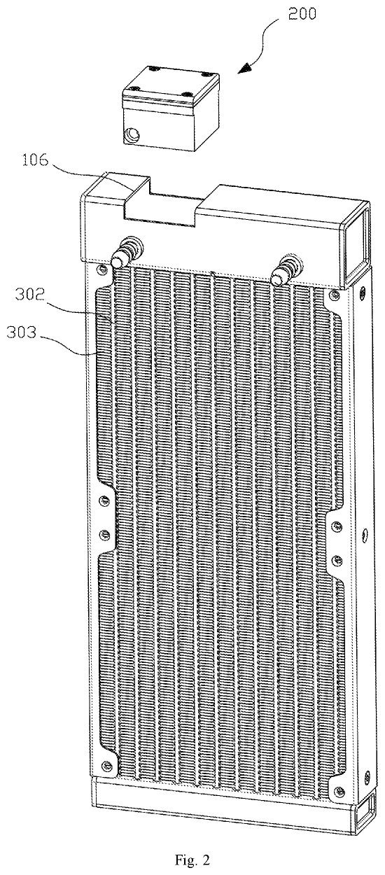

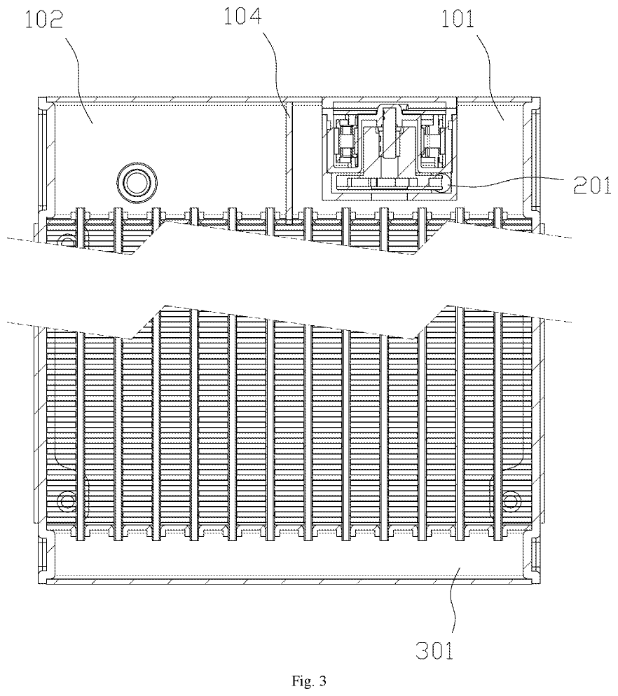

As shown in FIGS. 2 and 3, the heat dissipation device of this embodiment further includes a fourth water chamber 301, a plurality of cooling tubes 302 and a plurality of heat dissipation structure devices 303. The plurality of heat dissipation structure devices 303 are arranged at intervals, and each cooling tube 302 is arranged between adjacent heat dissipation structure devices 303. Preferably, the heat dissipation structure devices 303 are heat dissipation fins or heat dissipation wavy plates. Each of the plurality of cooling tubes 302 has one end in communication with a fourth water chamber 301, some of the cooling tubes 302 have the other end in communication with the first water chamber 100, and the remaining cooling tubes 302 have the other end in communication with the second water chamber 101. The first water chamber 100 is partitioned by a partition plate 104 into a second water chamber 101 and a third water chamber 102. One side of the third water chamber 102 is provided with a second interface 105 communicating therewith. That is, except for the structure of the first water chamber 100, the other structures of the heat dissipation device of this embodiment are the same as those of the related art, and their working principles will not be described in detail.

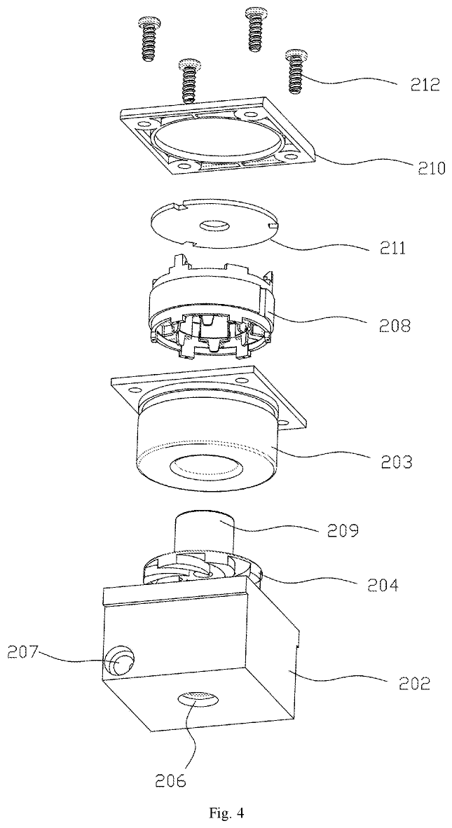

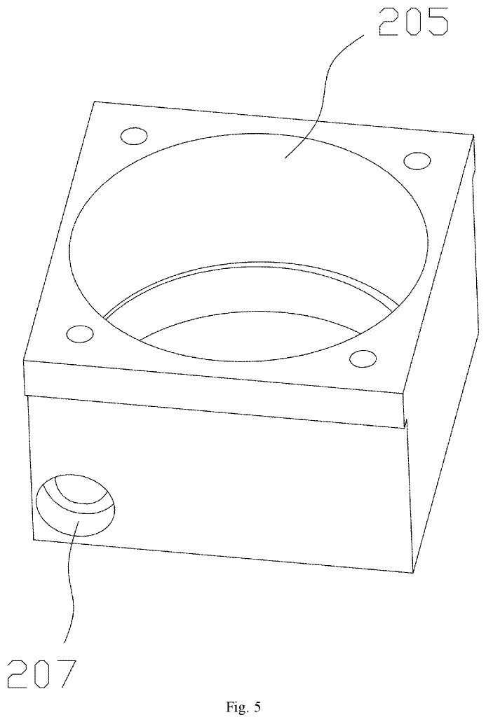

As shown in FIGS. 4 and 5, specifically, the pumping device 200 further includes a water pump base 202, a water pump shell 203 and an impeller 204. The first water chamber 100 is provided with a first opening 106, and the water pump base 202 is provided in an embedded manner in the first opening 106. The water pump base 202 is provided with a receiving cavity 205 with an opening end, the water pump shell 203 is provided in an embedded manner in the receiving cavity 205, the water pump water chamber 201 is formed between the water pump shell 203 and the water pump base 202, and the impeller 204 is received in the water pump water chamber 201. In addition, the pumping device 200 further includes a stator 208, a rotor 209, a water pump cover 210 and a main board 211. The rotor 209 is integrally formed with the impeller 204. Upper and lower ends of the water pump shell 203 are recessed to form receiving cavities 205 for mounting the stator 208 and the impeller 204, respectively. The stator 208 is arranged to rotate coaxially with the impeller 204. The screw 212 passes through the water pump cover 210 and the water pump shell 203 in sequence and is then fixed to the water pump base 202. The main board 211 controls the magnetic field intensity of the stator 208 to control the rotation speed of the rotor 209, and the rotation of the impeller 204 generates power for the liquid to flow through the water pump water chamber 201, so as to drive the liquid to circulate in the heat dissipation device.

As shown in FIGS. 3 and 4, the water pump base 202 is provided with a first water port 206 located below a rotating shaft of the impeller 204. A second water port 207, which is in communication with the water pump water chamber 201, is further provided on one side of the water pump base 202, and the second water port 207 is in communication with the first interface 103. That is, under the action of the impeller 204, the liquid in the first water chamber 100 flows into the water pump water chamber 201 through the first water port 206, and then flows out of the water pump water chamber 201 through the second water port 207 and enters the first interface 103. The first interface 103 may penetrate a side wall of the first water chamber 100 and be connected to the second water outlet 207, or may be connected thereto via a third structure such as a hose or a waterway.

In summary, an integrated liquid-cooled heat dissipation device of this embodiment adopts the scheme that the pumping device 200 and the first water chamber 100 are integrally arranged, and the pumping device 200 is embedded in the first water chamber 100, so that compared with the conventional heat dissipation device, the thickness of the heat dissipation device of the present invention is unchanged, thereby greatly reducing the occupied space and increasing the applicability of the present invention in the conventional environments. In addition, due to the integrated design of the pumping device 200 and the heat dissipation device, the circulation distance of the liquid in the heat dissipation device is reduced, the power attenuation of the pumping device 200 is less, and the heat exchange effect of the present invention is also improved.

Finally, it should be noted that the above embodiments are only used to illustrate the technical scheme of the present invention, and not to limit the scope of protection of the present invention. Although the present invention has been described in detail with reference to the preferred embodiments, those of ordinary skill in the art should understand that modifications and equivalent substitutions can be made to the technical scheme of the present invention without departing from the essence and scope of the technical scheme of the present invention.

1. An integrated liquid-cooled heat dissipation device, comprising a first water chamber (100), a pumping device (200) and a first interface (103), the first interface (103) being mounted on one side of the first water chamber (100), wherein
the pumping device (200) is provided in an embedded manner in the first water chamber (100), and the pumping device (200) comprises a water pump water chamber (201), which water pump water chamber (201) is in communication with the first interface (103) and an interior of the first water chamber (100).

2. The integrated liquid-cooled heat dissipation device of claim 1, wherein the pumping device (200) further comprises a water pump base (202), a water pump shell (203) and an impeller (204), the first water chamber (100) is provided with a first opening (106), and the water pump base (202) is provided in an embedded manner in the first opening (106); and the water pump base (202) is provided with a receiving cavity (205) with an opening end, the water pump shell (203) is provided in an embedded manner in the receiving cavity (205), the water pump water chamber (201) is formed between the water pump shell (203) and the water pump base (202), and the impeller (204) is received in the water pump water chamber (201).

3. The integrated liquid-cooled heat dissipation device of claim 2, wherein the water pump base (202) is provided with a first water port (206) located below a rotating shaft of the impeller (204); and a second water port (207), which is in communication with the water pump water chamber (201), is further provided on one side of the water pump base (202), and the second water port (207) is in communication with the first interface (103).

4. The integrated liquid-cooled heat dissipation device of claim 1, wherein the first water chamber (100) is internally provided with a partition plate (104) for partitioning the first water chamber (100), the first water chamber (100) is partitioned by the partition plate (104) to form a second water chamber (101) and a third water chamber (102), and the pumping device (200) is provided in an embedded manner in the second water chamber (101).

5. The integrated liquid-cooled heat dissipation device of claim 4, further comprising a fourth water chamber (301), a plurality of cooling tubes (302) and a plurality of heat dissipation structure devices (303), wherein the plurality of heat dissipation structure devices (303) are arranged at intervals, and each cooling tube (302) is arranged between adjacent heat dissipation structure devices (303); and each of the plurality of cooling tubes (302) has one end in communication with a fourth water chamber (301), some of the cooling tubes (302) have the other end in communication with the first water chamber (100), and the remaining cooling tubes (302) have the other end in communication with the second water chamber (101).

6. The integrated liquid-cooled heat dissipation device of claim 5, wherein the heat dissipation structure devices (303) are heat dissipation fins or heat dissipation wavy plates.
